(19) United States
(12) Patent Application Publication
(10) Pub. No.: US 2024/0251870 A1
(43) Pub. Date: Aug. 1, 2024

(54) Aerosol Generation Device with Battery Monitoring

(71) Applicant: JT International SA, Geneva (CH)

(72) Inventor: Grzegorz Aleksander Pilatowicz, Grens (CH)

(73) Assignee: JT International SA, Geneva (CH)

(21) Appl. No.: 18/565,321

(22) PCT Filed: Jun. 17, 2022
(86) PCT No.: PCT/EP2022/066585

§ 371 Date: Nov. 29, 2023

(30) Foreign Application Priority Data
Jun. 18, 2021 (EP) 21180387.9

(51) Int. Cl. A24F 40/53; A24F 40/20; A24F 40/51; A24F 40/60; A24F 40/95; G01R 31/3835; H02J 7/00

(52) U.S. Cl. CPC A24F 40/53; A24F 40/20; A24F 40/51; A24F 40/60; A24F 40/95; G01R 31/3835; H02J 7/0045; H02J 7/0049

(57) ABSTRACT

An aerosol generation device configured to aerosolise an aerosol generating consumable includes a battery configured to provide a power flow to a heater, and a controller configured to determine a voltage level of the battery. The voltage level of the battery is determined as a measured voltage of the battery when an elapsed time after a charging power flow to the battery has been inhibited is greater than or equal to a time threshold. The voltage level of the battery is determined as the measured voltage of the battery adjusted by a compensation factor when the elapsed time is less than the time threshold. The controller is further configured to control an indicator to indicate a number of remaining aerosolisation sessions that can be powered by the battery based upon the determined voltage level.

### FIELD OF INVENTION

The present invention relates to aerosol generation devices, and more specifically aerosol generation device power systems.

### BACKGROUND

Aerosol generation devices such as electronic cigarettes and other aerosol inhalers or vaporisation devices are becoming increasingly popular consumer products.

Heating devices for vaporisation or aerosolisation are known in the art. Such devices typically include a heating chamber and heater. In operation, an operator inserts the product to be aerosolised or vaporised into the heating chamber. The product is then heated with an electronic heater to vaporise the constituents of the product for the operator to inhale. In some examples, the product is a tobacco product similar to a traditional cigarette. Such devices are sometimes referred to as “heat not burn” devices in that the product is heated to the point of aerosolisation, without being combusted.

A problem faced by such aerosol generation devices includes providing an accurate indication of the charge level of the power system.

### SUMMARY OF INVENTION

In a first aspect, there is provided an aerosol generation device configured to aerosolise an aerosol generating consumable, the aerosol generation device comprising:
a battery configured to provide a power flow to a heater; and
a controller configured to determine a voltage level of the battery, wherein the voltage level of the battery is determined as a measured voltage of the battery when an elapsed time after a charging power flow to the battery has been inhibited is greater than or equal to a time threshold, and wherein the voltage level of the battery is determined as the measured voltage of the battery adjusted by a compensation factor when the elapsed time is less than the time threshold; and
wherein the controller is further configured to control an indicator to indicate a number of remaining aerosolisation sessions that can be powered by the battery based upon the determined voltage level.

In this way, an accurate and computationally efficient determination of the number of remaining aerosolisation sessions for which the battery is able to power is achieved. A measured battery voltage can be higher shortly after a charging power flow to the battery is inhibited than in a rested state; the accounting for an offset to the measured voltage after charging, compared to the rested state, with the compensation factor, improves the accuracy of the determination of the number of remaining aerosolisation sessions. This provides an accurate and computationally efficient determination of the number of remaining aerosolisation sessions that is consistent both immediately after charging the device and when the battery is in a rested state.

Adjusting the measured voltage of the battery can comprise compensating for an overvoltage in the measured voltage of the battery to determine a desired equilibrated battery voltage (i.e. the determined voltage level). The battery voltage (U_{BATT}) measured after a heating load or charging load is removed can be defined as U_{BATT}=U_{EQUILIBRATED}+U_{RELAXATION}. U_{RELAXATION} is the overvoltage (negative for discharging, and positive for charging). The controller can estimate U_{RELAXATION} as a function of time and subtract this to determine U_{EQUILIBRATED}. U_{EQUILIBRATED} (i.e. the determined voltage level) can then be used by the controller to evaluate the energy content of the battery to determine the number of remaining aerosolisation session that can be powered based upon the measured battery voltage U_{BATT}.

Preferably, the device comprises a handpiece and a charging case connectable to the handpiece, wherein the handpiece comprises the battery and the controller and is configured to aerosolise the aerosol generating consumable, and wherein the charging case is configured to charge the battery of the handpiece when the handpiece is connected to the charging case.

Such a two-part aerosol generation device advantageously improves the consumer experience as the handpiece can be made smaller, without a detriment to the number of aerosolisation session that can be powered due to the handpiece being connectable to the separate charging case.

Preferably, the controller is configured to determine the elapsed time after the charging power flow has been inhibited based upon an elapsed time after the handpiece has been disconnected from the charging case.

In this way, the controller determines that the charging has ended when the handpiece is disconnected from the charging case, so that the effect on the measured battery voltage can be accounted for.

Preferably, the indicator is configured to indicate a first number of remaining aerosolisation sessions when the controller determines that the voltage level of the battery is greater than or equal to a first voltage threshold.

Preferably, the indicator is configured to indicate a second number of remaining aerosolisation sessions when the controller determines that the voltage level of the battery is less than a second voltage threshold, wherein the second voltage threshold is lower than the first voltage threshold, and the second number of remaining aerosolisation sessions is less than the first number of remaining aerosolisation sessions.

Preferably, the indicator is configured to indicate a third number of remaining aerosolisation sessions when the controller determines that the voltage level of the battery is less than the first voltage threshold and greater than or equal to the second voltage threshold, wherein the third number of remaining aerosolisation sessions is less than the first number of aerosolisation sessions and greater than the second number of aerosolisation sessions.

In this way, the use of voltage thresholds obviates requirements for costly current measurement and other additional components when determining the remaining number of aerosolisation sessions that can be powered by the battery. Furthermore, this approach is robust and effective, taking the real battery state-of-charge into account. This also provides a more accurate determination of the number of aerosolisation sessions that the battery can power than, for example, counting how many times an aerosolisation session has been activated.

Preferably, the controller is configured to determine the voltage level of the battery as:
a measured voltage of the battery when a second elapsed time after the battery is at least partially discharged is greater than or equal to a second time threshold; and
the measured voltage of the battery adjusted by a second compensation factor when the second elapsed time is less than the second time threshold.

A measured battery voltage can be lower shortly after a discharging power flow from the battery (e.g. a power flow to the heater) is inhibited than in a rested state. As such, accounting for an offset to the measured voltage after a heating load is applied to the battery, compared to the rested state, with the second compensation factor, further improves the accuracy of the determination of the number of remaining aerosolisation sessions. This provides an accurate and computationally efficient determination of the number of remaining aerosolisation sessions that is consistent both immediately after the battery powers the heater and when the battery is in a rested state.

Preferably, the controller is further configured to determine whether the battery has been fully charged, and to indicate by the indicator the first number of remaining aerosolisation sessions when it is determined that the battery has been fully charged.

In this way, processing overheads at the controller can be reduced as the controller does not need to determine the battery voltage when the battery is fully charged.

Preferably, the controller is further configured to determine whether the battery has been fully charged by the charging case.

Preferably, the controller is configured to determine that the battery has been fully charged by determining that a control parameter is set to a state indicative of a full charge.

Preferably, the battery is a lithium iron phosphate battery.

Lithium iron phosphate is a beneficial battery technology for use in an aerosol generation device due to its high-power capability, long cycle life, high level of safety, thermodynamic stability and flat voltage curve that allows for delivering constant power over a wide range of state-of-charge without the need to use any compensation techniques.

Preferably, the aerosol generation device comprises a user input means operable in a first manner to trigger the aerosol generation device to aerosolise the aerosol generating consumable, and in a second manner to trigger controller to determine the voltage level of the battery and control the indicator to indicate the number of remaining aerosolisation sessions that can be powered by the battery based upon the determined voltage level.

In this way, a single user input means can be utilised for both determining the remaining number of aerosolisation sessions that can be powered, and for triggering an aerosolisation session. This allows for a more compact and simplified device arrangement, thereby improving the overall design of the device.

Preferably, the aerosol generation device further comprises a pulse width modulation module connected to the controller, wherein the pulse width modulation module is configured to convert the power flow from the battery to the heater to a pulse width modulated power flow.

In this way, a fixed power level can be output from the battery, and can then be adjusted before delivery to the heater.

Preferably, the aerosol generating consumable is a tobacco rod, and the aerosol generation device is configured to heat without burning the tobacco rod to produce an aerosol in an aerosolisation session.

In a second aspect, there is provided a method of operating an aerosol generation device configured to aerosolise an aerosol generating consumable, the aerosol generation device comprising a battery configured to provide a power flow to a heater, the method comprising:
determining an elapsed time since a charging power flow to the battery has been inhibited;
determining a voltage level of the battery;
wherein determining the voltage level of battery comprises determining the voltage level of the battery as a measured voltage of the battery when the elapsed time after the charging power flow to the battery has been inhibited is greater than or equal to a time threshold;
wherein determining the voltage level of battery comprises determining the voltage level of the battery as the measured voltage of the battery adjusted by a compensation factor when the elapsed time is less than the time threshold; and
controlling an indicator to indicate a number of remaining aerosolisation sessions that can be powered by the battery based upon the determined voltage level.

In a third aspect, there is provided a non-transitory computer-readable medium storing instructions that, when executed by one or more processors of a controller configured for operation with an aerosol generation device configured to aerosolise an aerosol generating consumable and comprising a battery configured to provide a power flow to a heater, cause the one or more processors to perform steps comprising:
determining, with a timer, an elapsed time since a charging power flow to the battery has been inhibited;
determining voltage level of the battery using a voltage sensor of the aerosol generation device;
wherein determining the voltage level of battery comprises determining the voltage level of the battery as a measured voltage of the battery when the elapsed time after the charging power flow to the battery has been inhibited is greater than or equal to a time threshold;
wherein determining the voltage level of battery comprises determining the voltage level of the battery as the measured voltage of the battery adjusted by a compensation factor when the elapsed time is less than the time threshold; and
controlling an indicator of the aerosol generation device to indicate a number of remaining aerosolisation sessions that can be powered by the battery based upon the determined voltage level.

The method of the second aspect and the non-transitory computer-readable medium of the third aspect can be combined with the preferable features of the first aspect, as appropriate.

### BRIEF DESCRIPTION OF THE DRAWINGS

Embodiments of the invention are now described, by way of example, with reference to the drawings, in which:

FIG. 1A is a perspective drawing of a two-part aerosolisation device having a handpiece and a charging case, with the handpiece stored within the charging case;

FIG. 1B is a perspective drawing of the two-part aerosolisation device with the handpiece partially separated from the charging case;

FIG. 2 is a block diagram of the two-part aerosolisation device;

FIG. 3 is a circuit diagram of the handpiece electronics of the two-part aerosolisation device;

FIG. 4 is a plot of state of charge against open circuit voltage for a charging cycle and a discharging cycle of an LFP battery configured to store enough energy to power an aerosol generation device for two aerosolisation sessions; and

FIG. 5 is a process flow diagram of processing steps performed by a controller of an aerosol generation device.

### DETAILED DESCRIPTION

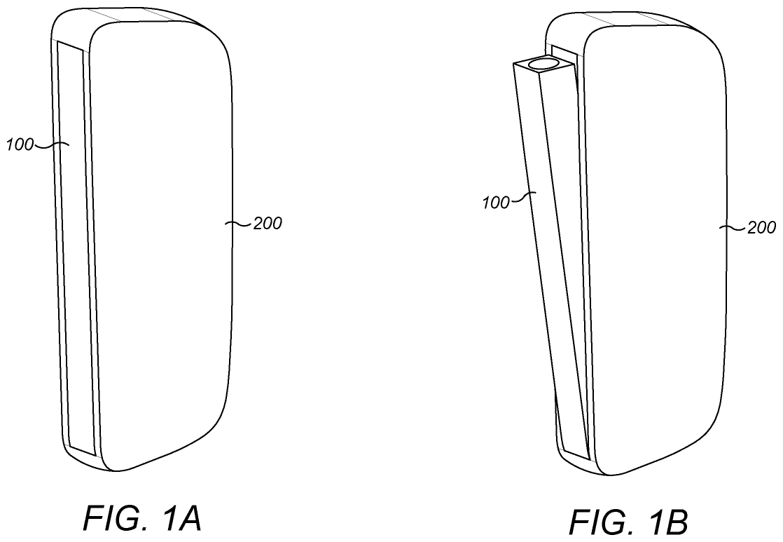

FIGS. 1A and 1B show perspective drawings of a two-part aerosolisation device having a handpiece 100 and a charging case 200. An aerosol generation device may also be referred to as a vapour generation device or electronic cigarette; for the purposes of the present disclosure, it will be understood that the terms aerosol and vapour are interchangeable.

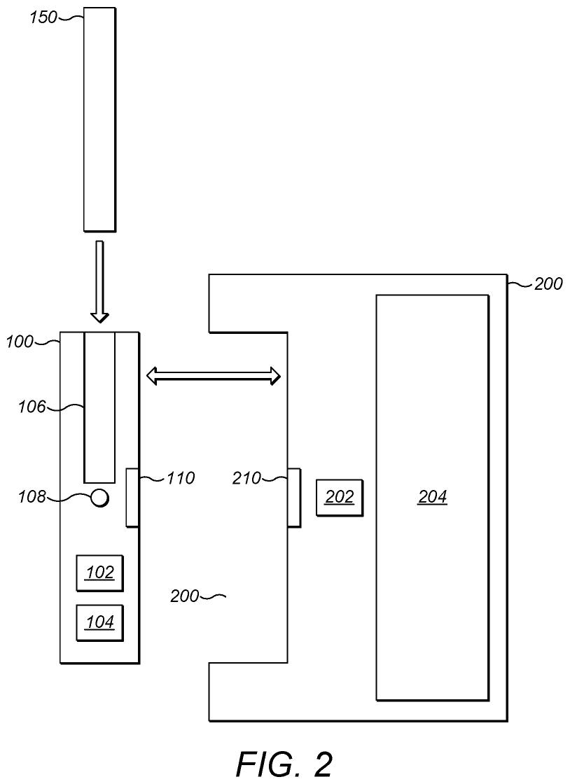

In FIG. 1A the handpiece 100 is stored within the charging case 200; in FIG. 1B the handpiece is partially removed from the charging case. FIG. 2 shows a block diagram of the handpiece 100 and charging case 200 in a separated arrangement.

The handpiece 100 is configured to aerosolise an aerosol generating consumable. The handpiece 100 comprises a battery 104, a controller 102, and a chamber 106 into which an aerosol generating consumable 150 can be received and heated to generate an aerosol.

In an example, a heater can be arranged in the chamber 106. The chamber 106 is accessed by an opening in the handpiece 100. The chamber 106 is arranged to receive the associated aerosol generating consumable 150.

The aerosol generating consumable 150 can contain an aerosol generating material, such as a tobacco rod containing tobacco. A tobacco rod can be similar to a traditional cigarette. The chamber has cross-section approximately equal to that of the aerosol generating consumable, and a depth such that when the associated aerosol generating consumable is inserted into the chamber, a first end portion of the aerosol generating consumable reaches a bottom portion of the chamber (that is, an end portion distal from the chamber opening), and a second end portion of the aerosol generating consumable distal to the first end portion extends outwardly from the chamber. In this way, a consumer can inhale upon the aerosol generating consumable when it is inserted into the handpiece.

The heater can be arranged in the chamber 106 such that the aerosol generating consumable 150 engages the heater when inserted into the chamber 106. The heater can be arranged as a tube in the chamber such that when the first end portion of the aerosol generating consumable 150 is inserted into the chamber the heater substantially or completely surrounds the portion of the aerosol generating consumable 150 within the chamber 106. The heater can be a wire, such as a coiled wire heater, or a ceramic heater, or any other suitable type of heater. The heater can comprise multiple heating elements sequentially arranged along the axial length of the chamber that can be independently activated (i.e. powered up) in a sequential order.

Alternatively, the heater can be arranged as an elongate piercing member (such as in the form of needle, rod or blade) within the chamber such that the heater can penetrate the aerosol generating consumable 150 and engage the aerosol generating material when the aerosol generating consumable 150 is inserted into the chamber.

Alternatively, the heater may be in the form of an induction heater. The heating element (i.e., a susceptor) can be provided in the consumable 150, and the heating element is inductively coupled to the induction element (i.e., induction coil) in the chamber when the consumable is inserted into the chamber. The induction heater can then heat the heating element by induction.

The heater can be arranged to heat the aerosol generating consumable 150 to a predetermined temperature to produce an aerosol in an aerosolisation session. An aerosolisation session can be considered as when the device is operated to produce an aerosol from the aerosol generating consumable. In an example in which the aerosol generating consumable 150 is a tobacco rod (such as in the example of FIG. 2), the aerosol generating consumable comprises tobacco. The heater is arranged to heat the tobacco, without burning the tobacco, to generate an aerosol. That is, the heater heats the tobacco at a predetermined temperature below the combustion point of the tobacco such that a tobacco-based aerosol is generated. The skilled person will readily understand that the aerosol generating consumable does not necessarily need to comprise tobacco, and that any other suitable substance for aerosolisation (or vaporisation), particularly by heating without burning the substance, can be used in place of tobacco.

In an alternative, the aerosol generating consumable can be a vaporisable liquid. The vaporisable liquid can be contained in a cartridge receivable in the handpiece, or can be directly deposited into the handpiece.

The battery 104 in the handpiece 100 can have a charge capacity suitable for powering a number of aerosolisation sessions. For example, the handpiece battery 104 may have a charge capacity, when in a fully charged state, sufficient to power to aerosolisation sessions (such as for aerosolising two tobacco rods).

In an example, the handpiece battery can be a lithium iron phosphate (LFP) battery. Lithium iron phosphate is a beneficial battery technology for use in the handpiece 100 due to its high-power capability, long cycle life, high level of safety thermodynamic stability, and flat voltage curve that allows for delivering constant power over a wide range of state-of-charge without the need to use any compensation techniques.

The handpiece 100 can comprise an indicator 108 that is arranged to indicate a number of remaining aerosolisation sessions that can be powered by the handpiece battery 104 based upon a determined voltage level of the battery 104. In an example, the indicator 108 may comprise a plurality of light sources (such as LEDs), wherein the number of illuminated LEDs corresponds to the number of remaining aerosolisation sessions that can be powered by the handpiece battery 104. In another, example the indicator 108 may be a display screen that presents the number of remaining aerosolisation sessions that can be powered by the handpiece battery 104 in a textual or visual manner.

The handpiece controller 102 is configured to control the operation of the handpiece 100, including a power flow from the handpiece battery 104 to the heater. The handpiece controller 102 can be at least one microcontroller unit comprising memory, with instructions stored thereon for operating the handpiece 100 including instructions for executing operating modes and controlling the power flows, and one or processors configured to execute the instructions.

The charging case 200 is connectable to the handpiece 100 and configured to charge the handpiece battery 104 when the handpiece 100 is connected to the charging case 200. The charging case 200 has a receiving area 220 into which the handpiece 100 is connected.

The charging case 200 comprises a charging case battery 204. Typically the battery 204 in the charging case 200 is of a greater capacity that the handpiece battery 104 in the handpiece 100. In this way, when the handpiece battery 104 is depleted, it can be recharged by the charging case 200. For example, the handpiece battery 104 may store sufficient charge for two aerosolisation sessions, and the charging case battery 204 may store sufficient charge to fully recharge the handpiece battery 104 ten times, such that the overall aerosol generation device (the handpiece 100 and the charging case 200) is capable of performing twenty aerosolisation sessions. The charging case battery 204 can be recharged from an external source, such as a wall adapter, power bank or USB connector.

The charging case 200 can also comprise a charging case controller 202 configured to manage the power flow from the charging case battery 204 to the handpiece battery 104.

The handpiece 100 can have a first connector 110 for power and/or data, and the charging case 200 can have a second connector 210 for power and/or data. The first connector 110 and second connector 210 are cooperating such that when the handpiece 100 is held within the receiving area 220, power can flow from the charging case 200 to the handpiece 100 in order to charge the handpiece battery 104 from the charging case battery 204.

In use, the operator removes the handpiece 100 from the charging case 200, and inserts an aerosol generating consumable 150 into the chamber 106. The operator can then operate a user input means to initiate the aerosolisation session. In response to this, the handpiece controller 102 controls a power flow from the handpiece battery 104 to the heater to pre-heat the heater to a predetermined aerosolisation temperature. The handpiece controller 102 then controls the power flow to maintain the heater and the aerosolisation temperature for the aerosolisation session. The operator draws on the end of the aerosol generating material 150 and inhales the generated aerosol. In an example, the aerosolisation session continues for a predetermined period of time, after which the handpiece controller 102 inhibits the power flow from the handpiece battery 104 to the heater. This predetermined period of time can correspond to the amount of time typically taken to aerosolise one consumable 150 (e.g. one tobacco rod). After completing the aerosolisation session, the operator places the handpiece 100 into the receiving place 220 in the charging case 200, and a power flow is initiated from the charging case battery 204 to the handpiece battery 104 to recharge the handpiece battery 104 for a subsequent aerosolisation session. In some examples, the handpiece battery 104 may be able to power multiple aerosolisation sessions (e.g. two aerosolisation sessions) before recharging; in this way, the operator does not need to reconnect the handpiece 100 to the charging case 200 between each aerosolisation session.

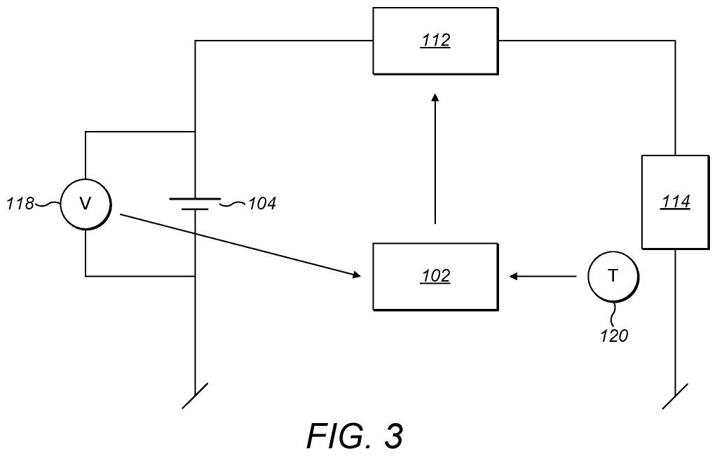

FIG. 3 shows an exemplary circuit diagram of the handpiece electronics. The handpiece electronics comprise the handpiece battery 104, the handpiece controller 102, and the heater component 114. The handpiece electronics can further comprise a pulse width modulation (PWM) module 112 that is controlled by the handpiece controller 102. The PWM module 112 is configured to apply a pulse width modulation to the power flow from the handpiece battery 104 to the heater component 114. The handpiece controller 102 can control the duty cycle of the pulse width modulation in order to control the power applied to heater. For example, when pre-heating, a high duty cycle can be applied to rapidly heat the heater. When the heater is being maintained at the aerosolisation temperature, a lower duty cycle can be applied. The PWM module can comprise a switch, such as a transistor, controlled by the handpiece controller 102 to switch between the “on state” and “off state” of each PWM period.

A temperature sensor 120 can be arranged at the heater or in the chamber 106 to monitor the heater temperature. The heater temperature is fed back to the handpiece controller 102. When the handpiece controller 102 determines that the heater temperature has moved above the aerosolisation temperature, the power level applied to the heater can be decreased (for example by reducing the PWM duty cycle). Likewise, when the handpiece controller 102 determines that the heater temperature has dropped below the aerosolisation temperature, the power level applied to the heater can be increased (for example by increasing the PWM duty cycle).

A voltage sensor or voltage sensing circuit 118 can be connected to the handpiece battery 104, to act as a voltmeter, and can feedback the battery voltage to the handpiece controller 102, so that the handpiece controller 102 can monitor the charge status of the handpiece battery 104 by determining the voltage level of the handpiece battery 104.

In FIG. 3, the respective connections between the handpiece controller 102 and the voltage sensor 118, PWM module 112 and temperature sensor 114 are represented by arrows for simplicity. However, the skilled person will understand that typical electrical connections between a controller and these components can be used.

The handpiece controller 102 is configured to determine the voltage level of the handpiece battery 104 and to control the indicator 108 to indicate a number of remaining aerosolisation sessions that can be powered by the handpiece battery 104 based upon the determined voltage level.

The voltage level of the handpiece battery 104 corresponds the number of aerosolisation sessions that can be powered by the handpiece battery 104.

The handpiece controller 102 can determine the number of remaining aerosolisation sessions that can be powered by the handpiece battery 104 by comparing the determined voltage level of the handpiece battery 104 to one or more voltage thresholds, wherein each voltage threshold is calibrated to correspond to a minimum battery voltage level required in the handpiece battery 104 to power a number of aerosolisation sessions. These voltage thresholds can be predetermined and stored in and accessed from storage associated with the handpiece controller 102.

In an example, a handpiece battery 104 can power two aerosolisation sessions when fully charged. When the determined voltage level of the handpiece battery 104 is greater than or equal to a first threshold, the charge level of the handpiece battery 104 can be deemed sufficient to power two aerosolisation sessions (i.e. the number of remaining aerosolisation sessions that can be powered by the handpiece battery 104 is two). When the determined voltage level of the handpiece battery 104 is below a second threshold, that is lower than the first threshold, the charge level of the handpiece battery 104 can be deemed insufficient to power an aerosolisation session (i.e. the number of remaining aerosolisation sessions that can be powered by the handpiece battery 104 is zero). When the determined voltage level of the handpiece battery 104 is less than the first voltage threshold and greater than or equal to the second voltage threshold (i.e. between the two thresholds), the charge level of the handpiece battery 104 can be deemed sufficient to power one aerosolisation session (i.e. the number of remaining aerosolisation sessions that can be powered by the handpiece battery 104 is one).

Whilst the foregoing uses the example of a handpiece battery 104 that can power two aerosolisation sessions, the skilled person will understand that the number of aerosolisation sessions need not be limited to two. For example, the handpiece battery 104 could power three aerosolisation sessions, and have three predetermined thresholds that demarcate how many sessions can be completed based upon the battery voltage level meeting or exceeding the thresholds. More generally, a handpiece battery 104 that can power N aerosolisation sessions can have N predetermined thresholds that demarcate how many of the N sessions can be completed based upon the battery voltage level.

In other words, the handpiece controller 102 can determine that a first number of remaining aerosolisation sessions (for example, two aerosolisation sessions) can be powered by the handpiece battery 104 when the handpiece controller 102 determines that the voltage level of the handpiece battery 104 is greater than or equal to a first voltage threshold. The indicator 108 is configured to indicate a first number of remaining aerosolisation sessions when the handpiece controller 102 determines that the voltage level of the handpiece battery 104 is greater than or equal to a first voltage threshold. The handpiece controller 102 can determine that a second number of remaining aerosolisation sessions (for example, zero aerosolisation sessions) can be powered by the handpiece battery 102 when the handpiece controller 102 determines that the voltage level of the handpiece battery 104 is less than a second voltage threshold, wherein the second voltage threshold is lower than the first voltage threshold, and the second number of remaining aerosolisation sessions is less than the first number of remaining aerosolisation sessions. The indicator 108 is configured to indicate a second number of remaining aerosolisation sessions when the handpiece controller 102 determines that the voltage level of the handpiece battery 104 is less than a second voltage threshold. The handpiece controller 102 can determine that a third number of remaining aerosolisation sessions (for example, one aerosolisation session) can be powered by the handpiece battery 104 when the handpiece controller 102 determines that the voltage level of the handpiece battery 104 is less than the first voltage threshold and greater than or equal to the second voltage threshold, wherein the third number of remaining aerosolisation sessions is less than the first number of aerosolisation sessions and greater than the second number of aerosolisation sessions. The indicator 108 is configured to indicate a third number of remaining aerosolisation sessions when the handpiece controller 102 determines that the voltage level of the handpiece battery 104 is less than the first voltage threshold and greater than or equal to the second voltage threshold.

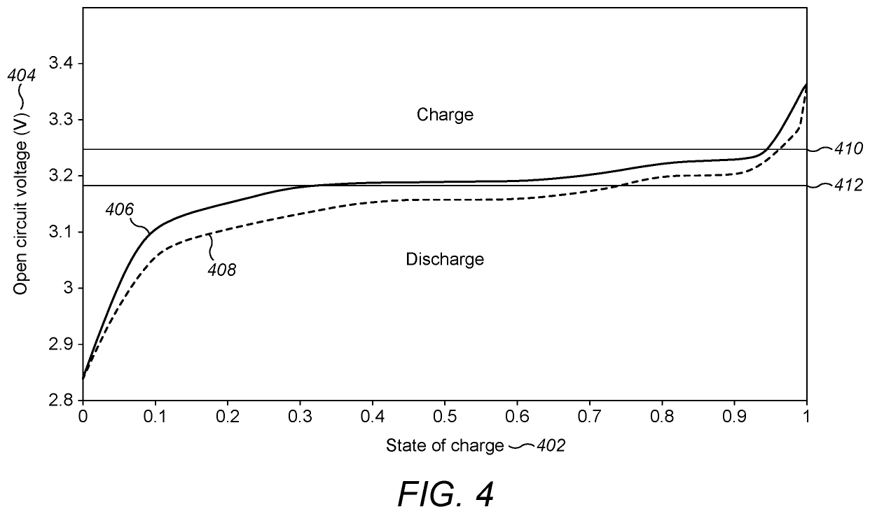

FIG. 4 shows an exemplary plot of state of charge 402 against open circuit voltage (V) 404 for a charging cycle 406 and a discharging cycle 408 for the specific example of an LFP battery configured as a handpiece battery 104 that can store enough energy to power an aerosol generation device handpiece for two aerosolisation sessions.

As can be seen in FIG. 4, the LFP battery has a flat voltage curve which can introduce problems meaning that, to leverage the aforementioned advantages of the LFP battery, accurate and expensive voltage measurement solutions might be used to avoid high error. For example these can include applying a current measurement to implement a Coulomb counting method which would require the implementation of a measurement shunt or other sensor, thereby adding costs, complexity and increasing device size. In another example, this can include using a bespoke battery fuel gauge integrated circuit, which again adds costs and complexity and increases the device size. The LFP battery is also characterised by a hysteresis effect, which causes different possible levels of voltage at the same state-of-charge depending whether we there was charge or discharge short-term history. This does not allow building simple relation between battery voltage and state-of-charge.

Comparing the measured voltage to the predetermined voltage thresholds to determine the number of aerosolisation sessions that the battery can power, as set forth in the present disclosure, overcomes these issues. The advantages of comparing the measured voltage to the predetermined voltage thresholds to determine the number of aerosolisation sessions that the battery can power, as set forth in the present disclosure can also be applied to other battery technologies, rather than only LFP batteries, to achieve an accurate and computationally efficient determination of the number of remaining aerosolisation sessions for which the handpiece battery is able to power.

For the battery of this example, an open circuit voltage of 3.25 V is predetermined as the minimum voltage required to power two aerosolisation sessions, and an open circuit voltage of 3.19 V is predetermined as the minimum voltage required to power one aerosolisation session. As such, in the example, the first threshold voltage 410 is 3.25 V and the second threshold voltage 412 is 3.19 V. For this battery, when the handpiece controller 102 determines that the voltage level of the battery is greater than or equal to 3.25 V (i.e. the first voltage threshold), the handpiece controller 102 determines that the battery has sufficient charge to power two aerosolisation sessions. When the handpiece controller 102 determines that the voltage level of the battery is less than 3.19 V (i.e. the second voltage threshold), the handpiece controller 102 determines that the battery cannot power any more aerosolisation sessions (i.e. the battery has sufficient charge to power zero aerosolisation sessions). When the handpiece controller 102 determines that the voltage level of the battery is less than 3.25 V (i.e. the first voltage threshold) and greater than or equal to 3.19 V (i.e. the second voltage threshold), the handpiece controller 102 determines that the battery has sufficient charge to power one aerosolisation session.

In addition to addressing the aforementioned problems associated with using an LFP battery, the voltage threshold technique of the present disclosure also does not require costly current measurement and any additional components. Furthermore, it is robust, effective and takes the real battery state-of-charge into account. This provides a more accurate determination of the number of aerosolisation sessions that the handpiece battery can power than, for example, counting how many times an aerosolisation session has been activated.

The predetermined voltage thresholds can be determined and stored in storage associated with and accessible by the handpiece controller 102 during a factory calibration stage. In some examples, the voltage thresholds may be based on average values determined for a plurality of batteries of the same type. In other examples, the voltage thresholds may be determined uniquely for each battery.

As explained, the handpiece 100 can be configured to display the indication of the number of remaining aerosolisation sessions in response to a user input. The user can trigger the handpiece controller 102 to determine the remaining number of aerosolisation sessions that can be powered by the handpiece battery 102 by pressing a button for example. In response to the user input, the handpiece controller 102 can determine the battery voltage using the voltage sensor 118 and comparing it to the predetermined voltage thresholds in order to determine the remaining number of aerosolisation sessions that can be powered by the handpiece battery 104. The handpiece controller 102 then controls the indicator 108 to display the number of remaining aerosolisation sessions to the operator.

In some examples, the user input means can be a button. For example, the user input means can be a dedicated button for monitoring the charge status of the handpiece battery 104. In another example, the handpiece 100 can have a button that triggers different functions when pressed in different manners (e.g. half-depressing or fully-depressing the button). The handpiece 100 can have a heater ignition button that triggers an aerosolisation session to begin. When the button is operated in a first manner (for example, being half-depressed, or a shorter press) it causes the handpiece controller 102 to determine the battery voltage and display the remaining number of aerosolisation sessions for which the handpiece battery 104 can power. When the button is operated in a second manner (for example, being fully-depressed, or a longer press) it triggers the handpiece controller 102 to control the device to being an aerosolisation session.

After a charging load (e.g. when the handpiece battery 104 is charged) or discharging load (e.g. when the handpiece battery 104 is powering the heater) is applied to the handpiece battery 104, the voltage level measured across the handpiece battery 104, by the handpiece controller 102 with the voltage sensor 118, may not provide a true representation of the number of sessions that can be powered. For a period of time after a charging load has been applied to the handpiece battery 104 (i.e. when the handpiece battery 104 is being charged), the measured voltage will be higher than that of a rested battery (i.e. a positive overvoltage is present in the measured battery voltage). As time elapses after the charging load has been removed, the voltage level drops to a rested battery state. Likewise, for a period of time after a discharging load has been applied to the handpiece battery 104 (i.e. the heating load when powering the heater), the measured voltage will be lower than that of a rested battery (i.e. a negative overvoltage is present in the measured battery voltage). That is, the measured battery voltage is lower than an equilibrated battery voltage or a recovered battery voltage following a rest period. As time elapses after the discharging load has been removed, the voltage level rises to a rested battery state.

As a consequence, immediately after the handpiece battery 104 has been charged, the determined voltage level could be higher than in a rested state, thereby giving an indication that a greater number of aerosolisation sessions can be powered than for which there is actually charge available. Likewise, immediately after the handpiece battery 104 has applied power to the heater, the determined voltage level could be lower than in a rested state, thereby giving an indication that a lesser number of aerosolisation sessions can be powered than for which there is actually charge available. The handpiece controller 102 can apply compensation factors to the measured voltage levels to account for these discrepancies so that an accurate and consistent indication of the number of available aerosolisation sessions can be provided immediately after charging and/or discharging the handpiece battery 104 as well as in the rested state.

After a charging power flow to the handpiece battery 104 has been inhibited (i.e. when the handpiece 100 has been removed from the charging case 200, or when the power flow from the charging case battery 204 to the handpiece battery 104 is inhibited), the handpiece controller 104 can adjust the measured handpiece battery voltage by a first compensation factor (or post-charging compensation factor) when the elapsed time after the charging power flow is removed is less than a first time threshold. This elapsed time can be considered a first elapsed time, or post-charging time, and the first time threshold can be considered a post-charging time threshold. The first compensation factor can be considered a calibration factor that is applied to the measured battery voltage in the time period after charging to adjust the measured battery voltage to be representative of that in a rested state.

The handpiece controller 102 can start a post-charging timer after detecting that the charging flow to the handpiece battery 104 has been inhibited, to monitor the post-charging time. When the handpiece controller 102 determines the voltage level of the handpiece battery 104, the handpiece controller 102 also compares the elapsed post-charging time to the post-charging time threshold.

When the handpiece controller 102 determines that the post-charging time is greater than or equal to the post-charging time threshold, the measured battery voltage is representative of a rested battery state as the battery will have had sufficient time to rest after the charging, and the first compensation factor is not applied. When the handpiece controller 102 determines that the post-charging time is less than the post-charging time threshold, the handpiece controller 102 adjusts the measured battery voltage by the first compensation factor. The first compensation factor can be predetermined and stored in memory associated with an accessible by the handpiece controller 102.

The first compensation factor can be varied as a function of the elapsed post-charging time. That is, the greater the elapsed time, the smaller the compensation factor as the handpiece battery 104 approaches the rested state. For example, the handpiece controller 102 can access a look-up of compensation factors for different elapsed post-charging times, and apply the compensation factor for the determined elapsed time. In this way, the measured voltage level can be accurately adjusted. In an alternative, the first compensation factor can be of a fixed value rather than time-varying. This can reduce the processing burden, compared to determining a time-varying compensation factor.

In other terms, the first compensation factor can be subtracted from the measured battery voltage to provide an adjusted battery voltage to take into account the voltage being higher after the charging is inhibited than in a rested state. In an example, the first time threshold after the charging is inhibited, can be 30 minutes.

After a heating load is removed from the handpiece battery 104 (i.e. when the battery ceases to power the heater), the handpiece controller 102 can adjust the measured battery voltage by a second compensation factor (or post-heating compensation factor) when the elapsed time after the heating load is removed is less than a second time threshold. This elapsed time can be considered a second elapsed time, or post-heating time, and the second time threshold can be considered a post-heating time threshold. The second compensation factor can be considered a calibration factor that is applied to the measured battery voltage in the time period after heating to adjust the measured battery voltage to be representative of that in a rested state.

The handpiece controller 102 can start a post-heating timer after detecting that the heating load has been removed from the handpiece battery 104, to monitor the post-heating time. When the handpiece controller 102 determines the voltage level of the handpiece battery 104, the handpiece controller 102 also compares the elapsed post-heating time to the post-heating time threshold.

When the handpiece controller 102 determines that the post-heating time is greater than or equal to the post-heating time threshold, the measured battery voltage is representative of a rested battery state as the handpiece battery 104 will have had sufficient time to rest after the heating load has been applied, and the second compensation factor is not applied. When the handpiece controller 102 determines that the post-heating time is less than the post-heating time threshold, the handpiece controller 102 adjusts the measured battery voltage by the second compensation factor. The second compensation factor can be predetermined and stored in memory associated with an accessible by the handpiece controller 102.

The second compensation factor can be varied as a function of the elapsed post-heating time. That is, the greater the elapsed time, the smaller the compensation factor as the handpiece battery 104 approaches the rested state. For example, the handpiece controller 102 can access a look-up of compensation factors for different elapsed post-heating times, and apply the compensation factor for the determined elapsed time. In this way, the measured voltage level can be accurately adjusted. In an alternative, the second compensation factor can be of a fixed value rather than time-varying. This can reduce the processing burden, compared to determining a time-varying compensation factor.

In other terms, the second compensation factor can be added to the measured battery voltage to provide an adjusted battery voltage to take into account the voltage being lower after the heating load is removed than in a rested state. In an example, the second time threshold after a heating load is removed from the handpiece battery, can be 30 minutes.

When the handpiece battery 104 is fully charged by the charging case 200, a charge state control parameter at the handpiece controller 102 can be set to a ‘fully charged’ state. For example, firmware of the handpiece controller 102 can have a parameter that is set to a logical state of 1 when the handpiece battery 104 is fully charged (the ‘fully charged’ state), and a logical state of 0 when the handpiece battery 104 is not fully charged (the ‘not fully charged’ state).

During the charging process, the charging case battery 204 provides charge to the handpiece battery 104 by the power connectors of the power/data connectors 110 and 210 between the handpiece 100 and the charging case 200. When the charging case controller 202 determines that the handpiece battery 104 is fully charged, it inhibits the power flow from the charging case battery 204 to the handpiece battery 104. The charging case controller 202 can then also set the charge state control parameter at the handpiece controller 102 to the ‘fully charged’ state using the data connectors of the power/data connectors 110 and 210. Alternatively, the handpiece controller 102 can detect that the handpiece battery 104 is fully charged and set the charge state control parameter to the ‘fully charged’ state.

When the handpiece battery 104 is subsequently (at least partially) discharged, for example when applying a heating load to the heater, the handpiece controller 102 can switch the parameter to the ‘not fully charged’ state.

When the handpiece controller 102 is triggered to determine the voltage level to determine the number of remaining aerosolisation sessions that can be powered by the handpiece battery 104, the handpiece controller 102 can first check the charge state control parameter before determining the handpiece battery voltage level. When the charge state control parameter is not set to indicate that the handpiece battery is fully charged (i.e. the charge state control parameter is in the ‘not fully charged’ state), the handpiece controller 102 continues on to determine the voltage level of the handpiece battery 104 (for example using the voltage sensor 118) in order to determine the number of remaining aerosolisation sessions that can be powered by the handpiece battery 104. When the charge state control parameter is set to indicate that the handpiece battery 104 is fully charged (i.e. the charge state control parameter is in the ‘fully charged’ state), the handpiece controller 102 does not determine the voltage level of the handpiece battery 104. Instead, the handpiece controller 102 determines that the handpiece battery 104 has sufficient energy to power the maximum number of aerosolisation sessions (two in the aforementioned LFP battery example) because the charge state control parameter indicates that the handpiece battery 104 is fully charged, and has not yet been discharged or partially discharged. In this way, processing overheads at the handpiece controller 102 can be reduced as the handpiece controller 102 does not determine the battery voltage when the battery is fully charged.

In light of the foregoing description, it can be learned that the handpiece controller 102 can determine the number of aerosolisation sessions for which the handpiece battery 104 has a sufficient charge level to power based upon a number of criteria.

The handpiece controller 102 can determine that the handpiece battery 104 has a sufficient charge level to power a first number of aerosolisation sessions (e.g. a maximum number of aerosolisation sessions, or two aerosolisation sessions in the earlier example of the LFP battery that can power up to two sessions) when the handpiece controller 102 determines at least one of:
The charge state control parameter is set to indicate that the handpiece battery 104 is fully charged (i.e. the charge state control parameter is in the ‘fully charged’ state);
The elapsed post-charging time is greater than or equal to the post-charging time threshold, and the measured battery voltage level is greater than or equal to the first voltage threshold;
The elapsed post-charging time is less than the post-charging time threshold, and the adjusted battery voltage level with the post-charging compensation factor is greater than or equal to the first voltage threshold;
The elapsed post-heating time is greater than or equal to the post-heating time threshold, and the measured battery voltage level is greater than or equal to the first voltage threshold; or
The elapsed post-heating time is less than the post-heating time threshold, and the adjusted battery voltage level with the post-heating compensation factor is greater than or equal to the first voltage threshold.

The handpiece controller 102 can determine that the handpiece battery 104 has a sufficient charge level to power a second number of aerosolisation sessions (e.g. zero aerosolisation sessions) when the handpiece controller 102 determines at least one of:
The elapsed post-charging time is greater than or equal to the post-charging time threshold, and the measured battery voltage level is less than the second voltage threshold;
The elapsed post-charging time is less than the post-charging time threshold, and the adjusted battery voltage level with the post-charging compensation factor is less than the second voltage threshold;
The elapsed post-heating time is greater than or equal to the post-heating time threshold, and the measured battery voltage level is less than the second voltage threshold; or
The elapsed post-heating time is less than the post-heating time threshold, and the adjusted battery voltage level with the post-heating compensation factor is less than the second voltage threshold.

The handpiece controller 102 can determine that the handpiece battery 104 has a sufficient charge level to power a third number of aerosolisation sessions (e.g. an intermediate number between the first and second numbers of aerosolisation sessions, or two aerosolisation sessions in the earlier example of the LFP battery that can power up to two sessions) when the handpiece controller 102 determines at least one of:
The elapsed post-charging time is greater than or equal to the post-charging time threshold, and the measured battery voltage level is less than the first voltage threshold and greater than or equal to the second voltage threshold;
The elapsed post-charging time is less than the post-charging time threshold, and the adjusted battery voltage level with the post-charging compensation factor is less than the first voltage threshold and greater than or equal to the second voltage threshold;
The elapsed post-heating time is greater than or equal to the post-heating time threshold, and the measured battery voltage level is less than the first voltage threshold and greater than or equal to the second voltage threshold; or
The elapsed post-heating time is less than the post-heating time threshold, and the adjusted battery voltage level with the post-heating compensation factor is less than the first voltage threshold and greater than or equal to the second voltage threshold.

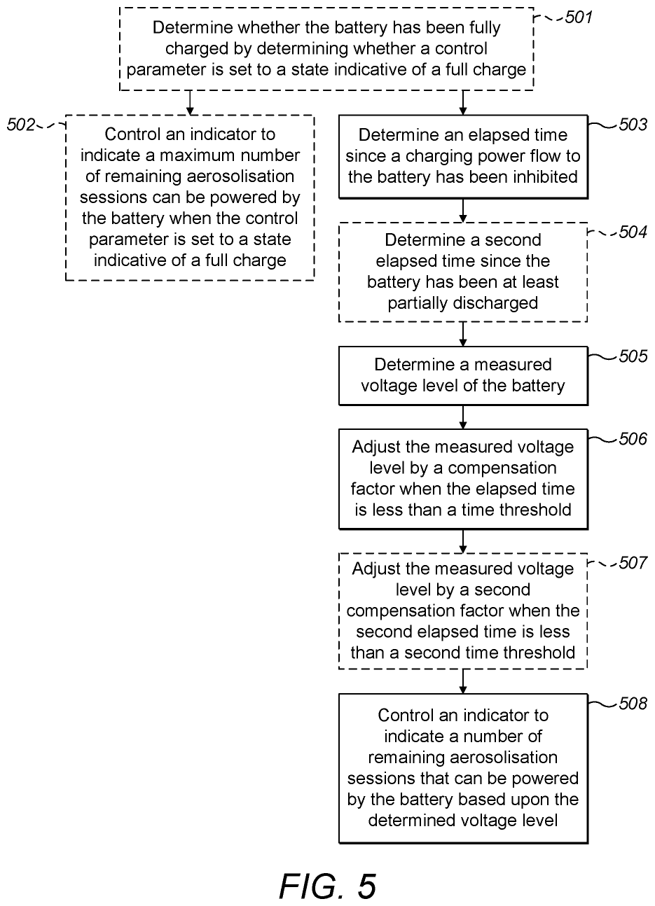

FIG. 5 shows an exemplary process flow of steps performed by the handpiece controller 102 in accordance with the foregoing description.

At step 503 the handpiece controller 102 determines an elapsed time (i.e. the first elapsed time) since a charging power flow to the handpiece battery 104 has been inhibited. Optionally, at step 504, the handpiece controller 102 determines the second elapsed time since the handpiece battery 104 has been at least partially discharged (e.g. the elapsed time since a power flow from the battery to the heater ended).

At step 505 the handpiece controller 102 determines a measured voltage level of the battery. At step 506 the handpiece controller 102 adjusts the measured voltage level by a compensation factor (i.e. the first compensation factor) when the elapsed time is less than a time threshold (i.e. the first time threshold). When the elapsed time is greater than or equal to the time threshold, the measured voltage level is not adjusted by the compensation factor.

Optionally at step 507 the handpiece controller 102 adjusts the measured voltage level by a second compensation factor when the second elapsed time is less than the second time threshold. When the second elapsed time is greater than or equal to the second time threshold, the measured voltage level is not adjusted by the second compensation factor.

In other words, the handpiece controller 102 can compensate for an overvoltage to in the measured battery voltage to determine the desired equilibrated battery voltage. The battery voltage (U_{BATT}) measured after the heating load or charging load is removed can be defined as U_{BATT}=U_{EQUILIBRATED}+U_{RELAXATION}. U_{RELAXATION} is the overvoltage (negative for discharging, and positive for charging). The controller can then estimate U_{RELAXATION} as a function of time and subtract this to determine U_{EQUILIBRATED}. U_{EQUILIBRATED} can then be used to evaluate the energy content of the battery based upon the measured battery voltage U_{BATT}.

If the handpiece controller 102 determines that both the first elapsed time is less than the first time threshold (post-charging), and the second elapsed time is less than the second time threshold (post-heating), the handpiece controller 102 can adjust the measured voltage level by both the first compensation factor and the second compensation factor.

At step 508, the handpiece controller 102 controls the indicator 108 to indicate the number of remaining aerosolisation sessions that can be powered by the battery based upon the determined voltage level.

Optionally, before step 503, the handpiece controller 102 can determine whether the handpiece battery 104 has been fully charged by determining whether the control parameter is set to a state indicative of a full charge. When the control parameter is set to a state indicative of a full charge, the process can continue to optional step 502 at which the handpiece controller 104 controls the indicator to indicate a maximum number of remaining aerosolisation sessions can be powered by the handpiece battery 104. When the control parameter is not set to a state indicative of a full charge, the process can continue to step 503.

The skilled person will readily understand that the process steps described with reference to FIG. 5 can be implemented in any suitable order. In an alternative process flow similar to that of FIG. 5, the handpiece controller 102 may be configured to perform steps 504 and 507 with steps 503 and 506 being optional. In another alternative process flow similar to that of FIG. 5, the handpiece controller 102 may be configure to perform steps 501 and 502, with steps 503-507 being optional.

Whilst the foregoing description describes the handpiece controller 102 performing the determination of the number of remaining aerosolisation sessions that can be powered by the handpiece battery 104, these processing steps could alternatively be performed by the charging case controller 202 communicating with the handpiece 100 by way of the data connectors 110 and 210 between the charging case 200 and handpiece 100. In such an alternative, the indicator 108 that indicates the number of remaining aerosolisation sessions could also be integrated into the charging case 200.

Whilst the foregoing description describes the aerosol generation device as a two-part system comprising a handpiece 100 and a charging case 200, in an alternative the aerosol generation device can be a one-part system comprising only the handpiece. In such an alternative, the handpiece can be charged from an external source such as a power bank or mains adapter; the first elapsed time can be based upon the period of time since the handpiece is disconnected from the external source. In such an alternative, the charge state control parameter can be set by the handpiece controller when determining that the battery is fully charged. In some examples of such an alternative, the handpiece can be configured to power a greater number of aerosolisation sessions than two when the battery is fully charged.

In the preceding description, the controller(s) can store instructions for controlling the aerosol generation device and power system in the described manners. The skilled person will readily understand that the controller(s) can be configured to execute any of the aforementioned manners in combination with one another as appropriate. The processing steps described herein carried out by the controller(s) may be stored in a non-transitory computer-readable medium, or storage, associated with the controller(s). A computer-readable medium can include non-volatile media and volatile media. Volatile media can include semiconductor memories and dynamic memories, amongst others. Non-volatile media can include optical disks and magnetic disks, amongst others.

It will be readily understood to the skilled person that the preceding embodiments in the foregoing description are not limiting; features of each embodiment may be incorporated into the other embodiments as appropriate.

1. An aerosol generation device configured to aerosolise an aerosol generating consumable, the aerosol generation device comprising:
a battery configured to provide a power flow to a heater; and
a controller configured to determine a voltage level of the battery, wherein the voltage level of the battery is determined as a measured voltage of the battery when an elapsed time after a charging power flow to the battery has been inhibited is greater than or equal to a time threshold, and wherein the voltage level of the battery is determined as the measured voltage of the battery adjusted by a compensation factor when the elapsed time is less than the time threshold; and
wherein the controller is further configured to control an indicator to indicate a number of remaining aerosolisation sessions that can be powered by the battery based upon the determined voltage level.

2. The aerosol generation device of claim 1, wherein the device comprises a handpiece and a charging case connectable to the handpiece, wherein the handpiece comprises the battery and the controller and is configured to aerosolise the aerosol generating consumable, and wherein the charging case is configured to charge the battery of the handpiece when the handpiece is connected to the charging case.

3. The aerosol generation device of claim 2, wherein the controller is configured to determine the elapsed time after the charging power flow has been inhibited based upon an elapsed time after the handpiece has been disconnected from the charging case.

4. The aerosol generation device of claim 1, wherein the indicator is configured to indicate a first number of remaining aerosolisation sessions when the controller determines that the voltage level of the battery is greater than or equal to a first voltage threshold.

5. The aerosol generation device of claim 4, wherein the indicator is configured to indicate a second number of remaining aerosolisation sessions when the controller determines that the voltage level of the battery is less than a second voltage threshold, wherein the second voltage threshold is lower than the first voltage threshold, and the second number of remaining aerosolisation sessions is less than the first number of remaining aerosolisation sessions.

6. The aerosol generation device of claim 5, wherein the indicator is configured to indicate a third number of remaining aerosolisation sessions when the controller determines that the voltage level of the battery is less than the first voltage threshold and greater than or equal to the second voltage threshold, wherein the third number of remaining aerosolisation sessions is less than the first number of aerosolisation sessions and greater than the second number of aerosolisation sessions.

7. The aerosol generation device of claim 1, wherein the controller is configured to determine the voltage level of the battery as:
a measured voltage of the battery when a second elapsed time after the battery is at least partially discharged is greater than or equal to a second time threshold; and
the measured voltage of the battery adjusted by a second compensation factor when the second elapsed time is less than the second time threshold.

8. The aerosol generation device of claim 4, wherein the controller is further configured to determine whether the battery has been fully charged, and to indicate by the indicator the first number of remaining aerosolisation sessions when it is determined that the battery has been fully charged.

9. The aerosol generation device of claim 8, wherein the controller is configured to determine that the battery has been fully charged by determining that a control parameter is set to a state indicative of a full charge.

10. The aerosol generation device of claim 1, wherein the battery is a lithium iron phosphate battery.

11. The aerosol generation device of claim 1, comprising a user input means operable in a first manner to trigger the aerosol generation device to aerosolise the aerosol generating consumable, and in a second manner to trigger controller to determine the voltage level of the battery and control the indicator to indicate the number of remaining aerosolisation sessions that can be powered by the battery based upon the determined voltage level.

12. The aerosol generation device of claim 1, further comprising a pulse width modulation module connected to the controller, wherein the pulse width modulation module is configured to convert the power flow from the battery to the heater to a pulse width modulated power flow.

13. The aerosol generation device of claim 1, wherein the aerosol generating consumable is a tobacco rod, and the aerosol generation device is configured to heat without burning the tobacco rod to produce an aerosol in an aerosolisation session.

14. A method of operating an aerosol generation device configured to aerosolise an aerosol generating consumable, the aerosol generation device comprising a battery configured to provide a power flow to a heater, the method comprising:
determining an elapsed time since a charging power flow to the battery has been inhibited;
determining a voltage level of the battery;
wherein determining the voltage level of battery comprises determining the voltage level of the battery as a measured voltage of the battery when the elapsed time after a charging power flow to the battery has been inhibited is greater than or equal to the time threshold;
wherein determining the voltage level of battery comprises determining the voltage level of the battery as the measured voltage of the battery adjusted by a compensation factor when the elapsed time is less than the time threshold; and
controlling an indicator to indicate a number of remaining aerosolisation sessions that can be powered by the battery based upon the determined voltage level.

15. A non-transitory computer-readable medium storing instructions that, when executed by one or more processors of a controller configured for operation with an aerosol generation device configured to aerosolise an aerosol generating consumable and comprising a battery configured to provide a power flow to a heater, cause the one or more processors to perform steps comprising:
determining, with a timer, an elapsed time since a charging power flow to the battery has been inhibited;
determining voltage level of the battery using a voltage sensor of the aerosol generation device;
wherein determining the voltage level of battery comprises determining the voltage level of the battery as a measured voltage of the battery when the elapsed time after the charging power flow to the battery has been inhibited is greater than or equal to a time threshold;
wherein determining the voltage level of battery comprises determining the voltage level of the battery as the measured voltage of the battery adjusted by a compensation factor when the elapsed time is less than the time threshold; and
controlling an indicator of the aerosol generation device to indicate a number of remaining aerosolisation sessions that can be powered by the battery based upon the determined voltage level.
